(19) United States
(12) Patent Application Publication
(10) Pub. No.: US 2021/0371608 A1
(43) Pub. Date: Dec. 2, 2021

(54) THERMALLY CONDUCTIVE DIELECTRIC FILM

(71) Applicant: 3M INNOVATIVE PROPERTIES COMPANY, St. Paul, MN (US)

(72) Inventors: Mario A. Perez, Burnsville, MN (US); Jeremy M. Higgins, Roseville, MN (US); Clint J. Novotny, Arlington, VA (US); Mitchell T. Huang, Austin, TX (US)

(21) Appl. No.: 16/632,979

(22) PCT Filed: Jul. 30, 2018
(86) PCT No.: PCT/IB2018/055674

§ 371 Date: Jan. 22, 2020

Related U.S. Application Data
(60) Provisional application No. 62/541,929, filed on Aug. 7, 2017.

(51) Int. Cl. C08J 5/18; H05K 7/20; B29C 48/00; B29C 48/08; C08L 67/02

(52) U.S. Cl. CPC C08J 5/18; H05K 7/2039; B29C 48/0018; B29K 2067/003; B29C 48/08; C08L 67/02; B29C 48/022

(57) ABSTRACT

A thermally conductive dielectric film includes a thermoplastic layer including polyester segments and 5 to 30% by wt polyether amide segments. The thermally conductive dielectric film has a thickness of less than 100 micrometers.

### BACKGROUND

Heat is an undesirable by-product in the operation of electrical devices, such as, motors, generators, and transformers. Elevated operating temperatures can reduce device reliability and lifetime. The dissipation of heat also imposes constraints on device design and hinder the ability to achieve higher power density devices. Electrical insulation materials typically have low thermal conductivity, which can limit heat dissipation in electrical devices.

Polyethylene terephthalate films are widely used as electrical insulation within motors, generators, transformers, and many other applications. For higher performance applications, where higher temperature and/or higher chemical resistance are needed, polyimide films are used.

### SUMMARY

The present disclosure relates to oriented thermally conductive dielectric films. In particular, the dielectric films include polyester segments and polyether amide segments.

In one aspect, a thermally conductive dielectric film includes a thermoplastic layer including polyester segments and 5 to 30% by wt polyether amide segments. The thermally conductive dielectric film has a thickness of less than 100 micrometers.

In another aspect, a thermally conductive dielectric film includes a thermoplastic layer including polyester segments and 5 to 30% by wt polyether amide segments and a thermally conductive filler dispersed in the thermoplastic layer. The thermally conductive dielectric film has a thickness of 100 micrometers or less.

These and various other features and advantages will be apparent from a reading of the following detailed description.

### DETAILED DESCRIPTION

In the following detailed description, reference is made to the accompanying drawings that form a part hereof, and in which are shown by way of illustration several specific embodiments. It is to be understood that other embodiments are contemplated and may be made without departing from the scope or spirit of the present disclosure. The following detailed description, therefore, is not to be taken in a limiting sense.

All scientific and technical terms used herein have meanings commonly used in the art unless otherwise specified. The definitions provided herein are to facilitate understanding of certain terms used frequently herein and are not meant to limit the scope of the present disclosure.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the properties sought to be obtained by those skilled in the art utilizing the teachings disclosed herein.

The recitation of numerical ranges by endpoints includes all numbers subsumed within that range (e.g. 1 to 5 includes 1, 1.5, 2, 2.75, 3, 3.80, 4, and 5) and any range within that range.

As used in this specification and the appended claims, the singular forms “a”, “an”, and “the” encompass embodiments having plural referents, unless the content clearly dictates otherwise.

As used in this specification and the appended claims, the term “or” is generally employed in its sense including “and/or” unless the content clearly dictates otherwise.

As used herein, “have”, “having”, “include”, “including”, “comprise”, “comprising” or the like are used in their open-ended sense, and generally mean “including, but not limited to”. It will be understood that “consisting essentially of”, “consisting of”, and the like are subsumed in “comprising,” and the like.

“Polymer” refers to, unless otherwise indicated, polymers and copolymers (i.e., polymers formed from two or more monomers or comonomers, including terpolymers, for example), as well as copolymers or polymers that can be formed in a miscible blend by, for example, coextrusion or reaction, including transesterification, for example. Block, random, graft, and alternating polymers are included, unless indicated otherwise.

“Polyester” refers to a polymer that contains an ester functional group in the main polymer chain. Copolyesters are included in the term “polyester”.

“Polyether amide” or “PEBA” refers to polyether block amide and may be a block copolymer obtained by polycondensation of a carboxylic acid polyamide with an alcohol terminated polyether. The general chemical structure for polyether amide is HO-(CO-PA-CO-PE-)ₙ-H, where PA is polyamide and PE is polyether.

The present disclosure relates to thermally conductive dielectric films. In particular the films are thermoplastic films with polyester segments and polyether amide segments. The thermoplastic layer may include polyester segments and 5 to 30% by wt polyether amide segments, or 5 to 20% by wt polyether amide segments. The thermally conductive dielectric film may be orientated (by stretching). The oriented high thermal conductivity films and sheets described herein may be formed via biaxial (sequential or simultaneous) or uniaxial stretching. The films described herein have high elongation to break values. The thermally conductive dielectric film has a thickness of less than 100 micrometers. The films described herein have thermal conductivities (through the plane) greater than 0.20 W/(m-K) or greater, or 0.25 W/(m-K) or greater, or 0.3 W/(m-K) or greater, with dielectric strengths of at least 50 KV/mm, or at least 60 kV/mm, or at least 65 kV/mm. These thermally conductive dielectric films may be filled with thermally conductive inorganic particles. These thermally conductive inorganic particles may be homogenous spherical or substantially spherical particles. These films can be utilized in many areas of thermal management that lead to higher equipment efficiencies and lower operating temperatures with potentially higher power delivery per unit volume. While the present disclosure is not so limited, an appreciation of various aspects of the disclosure will be gained through a discussion of the examples provided below.

The thermally conductive dielectric film or thermoplastic layer described herein is formed of polyester segments and polyether amide (PEBA) segments. The polyester component may be any useful polyester such as polyethylene terephthalate (PET) or polyethylene naphthalate (PEN), or copolymers thereof.

The polyester polymeric materials may be made by reactions of terephthalate dicarboxylic acid (or ester) with ethylene glycol. In some embodiments, the polyester is generally made by reactions of terephthalate dicarboxylic acid (or ester) with ethylene glycol and at least one additional comonomer that contributes branched or cyclic C₂-C₁₀ alkyl units.

Suitable terephthalate carboxylate monomer molecules for use in forming the terephthalate subunits of the polyester include terephthalate carboxylate monomers that have two or more carboxylic acid or ester functional groups. The terephthalate carboxylate monomer may include terephthalate dicarboxylic acid such as 2,6-terephthalate dicarboxylic acid monomer and isomers thereof.

The polyester may include a branched or cyclic C₂-C₁₀ alkyl unit that is derived from a branched or cyclic C₂-C₁₀ alkyl glycol such as neopentyl glycol, cyclohexanedimethanol, and mixtures thereof. The branched or cyclic C₂-C₁₀ alkyl unit may be present in the polyester layer or film in an amount less than 2 mol %, or less than 1.5 mol %, or less than 1 mol %, based on total mol % of ethylene and branched or cyclic C₂-C₁₀ alkyl units used to from the polyester material.

The thermoplastic layer described herein includes polyester segments and polyether amide segments. Polyether amide segments make up 5 to 30% by wt, or 5 to 20% wt of the thermoplastic layer. Polyester segments make of from 95 to 70% by weight, or from 95 to 80% by weight of the thermoplastic layer. Polyether amide improves mechanical properties of the thermoplastic layer, such as improved elongation and toughness while maintaining high thermal conductivity.

The thermoplastic layer may have a thickness of less than 150 micrometers, or less than 125 micrometers, or less than 100 micrometers, or less than 75 micrometers, or less than 50 micrometers, or in a range from 10 to 150 micrometers, or in a range from 20 to 125 micrometers, or in a range from 25 to 100 micrometers, or from 25 to 75 micrometers, or from 25 to 50 micrometers, or from 25 to 40 micrometers.

The thermoplastic layer may be unfilled, or substantially free of inorganic filler material or particles. The thermoplastic layer may contain less than 0.1% inorganic filler material or particles. The thermoplastic layer may be formed of only thermoplastic material. The thermoplastic layer may be formed of only polyester and polyetherimide thermoplastic material.

Thermoplastic layers with polyester segments and polyether amide segments and no inorganic fillers may have a Graves area per mil value of at least 100 (lbs*% displacement)/mil, or at least 200 (lbs*% displacement)/mil, or at least 300 (lbs*% displacement)/mil, or at least 350 (lbs*% displacement)/mil. These thermoplastic layers may have a thermal conductivity value of 0.20 W/(m-K) or greater, or 0.25 W/(m-K) or greater, or 0.3 W/(m-K) or greater. These thermoplastic layers may have a dielectric or breakdown strength of at least 50 kV/mm, or at least 60 kV/mm, or at least 65 kV/mm. These thermoplastic layers may be referred to a ‘dielectric’.

In some embodiments, the thermally conductive dielectric film includes a thermoplastic layer including polyester segments and 5 to 30% by wt, or 5 to 20% by wt polyether amide segments, a thermally conductive filler dispersed in the thermoplastic layer, and a thickness of 100 micrometers or less. Inorganic fillers tend to decrease mechanical properties.

The thermally conductive dielectric film may include filler or inorganic particles dispersed within or throughout the thermoplastic layer. The filler or inorganic particles may be thermally conductive filler material.

In some embodiments, the thermally conductive filler includes at least 10% wt., or at least 20% wt., or at least 25% wt., or at least 30% wt., or at least 35% wt., or at least 40% wt., or at least 50% wt. of the thermoplastic layer. The thermoplastic layer may include the thermally conductive filler in a range from 10% wt. to 60% wt., or from 20% wt. to 50% wt.

The thermally conductive filler may be any useful filler material that may have a thermal conductivity value greater than a thermal conductivity value of the polymer it is dispersed within. In many embodiments, the thermally conductive filler has a thermal conductivity value that is greater than 1 W/(m-K) or greater than 1.5 W/(m-K) or greater than 2 W/(m-K) or greater than 5 W/(m-K) or greater than 10 W/(m-K).

Exemplary thermally conductive filler includes for example, alumina, metal oxides, metal nitrides, and metal carbides. In many embodiments, the thermally conductive filler includes, for example, alumina, boron nitride, aluminum nitride, aluminum oxide, beryllium oxide, magnesium oxide, thorium oxide, zinc oxide, silicon nitride, silicon carbide, silicon oxide, diamond, copper, silver, and graphite and mixtures thereof.

The thermally conductive filler may have any useful particle size. In many embodiments, the thermally conductive filler has a size in a range from 1 to 100 micrometers or from 1 to 20 micrometers. In many embodiments, the thermally conductive filler has a D₉₉ value of 25 micrometers or less, or 20 micrometers or less, or 15 micrometers or less, or 10 micrometers or less. The thermally conductive filler may have a median size value in a range from 1 to 7 micrometers, or from 1 to 5 micrometers, or from 1 to 3 micrometers. One method to determine particle size is described in ASTM Standard D4464 and utilizes laser diffraction (laser scattering) on a Horiba LA 960 particle size analyzer.

In some embodiments, substantially all the thermally conductive filler may be spherical or semi-spherical. Useful spherical or semi-spherical alumina particles are commercially available under the trade designation AY2-75 from Nippon Steel & Sumikin Materials Co. Hyogo, Japan. Useful spherical or semi-spherical alumina particles are commercially available under the trade designation Martoxid TM 1250 from Huber/Martinswerk, GmbH, Bergheim, Germany.

Thermoplastic layers with polyester segments and polyether amide segments and thermally conductive filler may have a Graves area per mil value of at least 10 (lbs*% displacement)/mil, or at least 20 (lbs*% displacement)/mil, or at least 30 (lbs*% displacement)/mil, or at least 50 (lbs*% displacement)/mil. These thermoplastic layers may have a thermal conductivity value of 0.20 W/(m-K) or greater, or 0.25 W/(m-K) or greater, or 0.3 W/(m-K) or greater. These thermoplastic layers may have a dielectric or breakdown strength of at least 50 kV/mm, or at least 60 kV/mm, or at least 65 kV/mm. These thermoplastic layers may be referred to a ‘dielectric’.

The thermally conductive dielectric film described herein may be formed by compounding polyester and polyether amide material to for the thermoplastic material. In embodiments that include a thermally conductive filler, the thermally conductive filler is dispersed in the thermoplastic material. The thermoplastic material forms a thermoplastic layer. In orientated embodiments, the thermoplastic layer is then stretched to form the oriented thermoplastic layer (filled or unfilled). The stretching step may uniaxially or biaxially orient filled or unfilled thermoplastic layer to form a uniaxially or biaxially oriented filled or unfilled thermoplastic film.

The thermally conductive and oriented thermoplastic film can be stretched in one or orthogonal directions in any useful amount. In many embodiments, the thermally conductive and oriented thermoplastic film can be stretched to double (2×2) or triple (3×3) a length and/or width of the original cast film or any combination thereof such as a 2×3, for example.

Even though the thermally conductive film is stretched to orient the film, voids in the final film are not present. Any voids that may be created during the stretching or orienting process can be filled be removed by heat treating. It is surprising that these thermally conductive film

The final thickness of the thermally conductive and oriented thermoplastic film can be any useful value. In many embodiments, final thickness of the thermally conductive and oriented thermoplastic film is in a range from 25 to 125 micrometers, or from 25 to 100 micrometers or from 25 to 75 micrometers or from 25 to 50 micrometers, or from 25 to 40 micrometers.

The thermally conductive dielectric film can be adhered to a non-woven fabric or material. The thermally conductive dielectric film can be adhered to a non-woven fabric or material with an adhesive material. The thermally conductive dielectric film and film articles described herein can be incorporated into motor slot insulation and dry type transformer insulation. The thermally conductive dielectric film may form a backing of a tape with the addition of an adhesive layer disposed on the thermally conductive and oriented thermoplastic film. The additional adhesive layer may be any useful adhesive such as a pressure sensitive adhesive.

Objects and advantages of this disclosure are further illustrated by the following examples, but the particular materials and amounts thereof recited in these examples, as well as other conditions and details, should not be construed to unduly limit this disclosure.

### Examples

All parts, percentages, ratios, etc. in the examples are by weight, unless noted otherwise. Solvents and other reagents used were obtained from Sigma-Aldrich Corp., St. Louis, Mo. unless specified differently.

Materials

| Abbreviation | Description |
|---|---|
| PET | Polyethyleneterephthalate Tairllin N404. Nan Ya Plastics |
| | Corp. America. Lake City, N.C. |
| R1 | Copolyester Laser + C 9921, available from DAK |
| | Americas LLC, Charlotte, NC. |
| R2 | Polyether block amide copolymer, Pebax 4533 SP01, |
| | available from Arkema Canada, Inc. Burlington, ON |
| F1 | FUS-SIL Silica - Silica, FUS-SIL 550. Ceradyne Inc. |
| | A 3M Company. Midway, TN. |

Procedure for Making Cast Sheets:

All cast sheets were made with an 18 mm twin screw extruder made by LEISTRITZ EXTRUSIONSTECHINK GMBH, Nuremberg, Germany and instrumented by Haake Inc (now ThermoScientific Inc.) and sold as a Haake Polylab Micro18 System. Screw speed was held at 350 RPM. Extrusion rates ranged from 40 to 70 grams per minute. All thermoplastics in pellet form were fed into the twin screw with a K-tron feeder model KCL24/KQX4 made by Ktron America, Pitman, N.J. Fillers were fed with a Techweigh volumetric feeder made by Technetic Industries, St. Paul, Minn. A 4 inch coat-hanger die was utilized for this purpose. Final sheet thicknesses in the range of 0.5 to 0.8 mm were obtained.

Procedure for Batch Stretching Cast Sheets:

Squares of 58×58 mm were cut from the original cast sheets. The squares were loaded and stretched using an Accupull biaxial film stretcher made by Inventure Laboratories Inc., Knoxville, Tenn. A temperature of 100 C was set in all zones of the machine unless mentioned otherwise. Films were stretched at speeds ranging from 2-25 mm/min. A preheat of 30 seconds was chosen. The post heat was varied from 30 to 90 seconds. During the post heat the film is clamped at the maximum stretch reached during the cycle.

Tests

Mechanical Tests:

Graves tear: Graves tear tests were performed according to ASTM D 1004-13 Tear Resistance (Graves Tear) of Plastic Film and Sheeting. For our case, MD signifies that the specimens were made so that the tear propagates along the machine direction of the film. TD for a tear propagation along the transverse direction. These tests and the tensile tests were conducted in an Instron Universal Testing machine model 2511 using a 500 N load cell (Bighamton, N.J.).

Tensile Modulus, Tensile Strength, Elongation: These tests were conducted on an Instron Universal Testing machine (Norwood, Mass.) using a 500 Newton load cell. The cross-head speed was 2 inches per minute as prescribed by ASTM D638-08.

Thermal Tests:

Thermal conductivity: Thermal conductivity was calculated from thermal diffusivity, heat capacity, and density measurements according the formula:

k=α·cₚ·ρ

where k is the thermal conductivity in W/(m K), α is the thermal diffusivity in mm²/s, cₚ is the specific heat capacity in J/K-g, and ρ is the density in g/cm³. The sample thermal diffusivity was measured using a Netzsch LFA 467 “HyperFlash” directly and relative to standard, respectively, according to ASTM E1461-13. Sample density was measured using a Micromeritics AccuPyc 1330 Pycnometer, while the specific heat capacity was measured using a TA Instruments Q2000 Differential Scanning calorimeter with Sapphire as a method standard.

Electrical Tests:

Dielectric strength: The dielectric breakdown strength measurements were performed according to ASTM D149-97a (Reapproved 2004) with the Phenix Technologies Model 6TC4100-10/50-2/D149 that is specifically designed for testing in the 1-50 kV, 60 Hz (higher voltage) breakdown range. Each measurement was performed while the sample was immersed in the fluid indicated. The average breakdown strength is based on an average of measurements up to 10 or more samples. For this experiment we utilized, as is typical, a frequency of 60 Hz and a ramp rate of 500 volts per second.

Sample Preparation

Samples were prepared and tested using the appropriate materials and procedures listed above and noted in Table 1 for each sample.

Results

Table 1 below shows that the mechanical properties of these blends have a toughening advantage over the neat polymer and its filled version. Graves tear maximum force and area are both superior for the R1/R2 mixture shown below compared to those of unfilled PET compounds, i.e. R1 alone and reference. The mixture also shows much higher elongation which in turn reflects on the toughness of the compound. It can also be noted from Table 1 that properties related to toughness and tear are lower when R1 is filled to a high level (45% by weight). The addition of R2 improves these properties for the filled material (Tensile elongation and Graves area). The properties of a typical PET utilized for these applications at our manufacturing facility is also included here as a reference point. Thermal conductivities are provided in Table 2. It is shown in this table that the addition of R2 improves thermal conductivity of R1 and is not detrimental to the filled composition. Dielectric breakdown strength is shown in table 3. It can be noted that all compositions are electrically insulating. Filled and unfilled compositions have similar breakdown strengths. All loadings in these tables are in % by weight. All samples with the exception of the PET standard were stretched to 2.5× in both directions at a temperature of 120 C.

TABLE 1
Mechanical properties of control and composite materials.

| | | | | | Graves | Graves |
|---|---|---|---|---|---|---|
| | | | | | Max | Area |
| | | Tensile | Tensile | | Force | Pounds |
| | Thickness | Modulus | Strength | Elongation | Pounds | Force × |
| Material | mils | Psi | Psi | % | Force/mil | %/mil |
| PET Standard Film MD, | 5 | 433660 | 21800 | 134 | 4.7 | 50.4 |
| stretch not known | | | | | | |
| PET Standard Film TD, | 5 | 543700 | 30230 | 105 | 4.4 | 63.8 |
| stretch not known | | | | | | |
| R1, MD | 1.5 | 385000 | 10600 | 56 | 3.1 | 130 |
| 80% R1/20% R2, MD | 2.3 | 224300 | 7610 | 287 | 4.9 | 364 |
| 45% F1 in R1, MD | 3.2 | 459700 | 7860 | 9.4 | 1.7 | 1.4 |
| 45% F1 in 80% R1/ | 3.7 | 226000 | 5700 | 58.8 | 1.6 | 15 |
| 20% R2, MD | | | | | | |

TABLE 2
Thermal conductivity.

| | | | Thermal |
|---|---|---|---|
| | | Thermal | Conductivity |
| | Thickness | Conductivity | Uncertainty |
| Material | mm | W/m-K | W/m-K |
| R1 | 0.07 | 0.17 | 0.02 |
| 80% R1, 20% R2 | 0.08 | 0.24 | 0.07 |
| 45% F1 in R1 | 0.08 | 0.26 | 0.02 |
| 45% F1 in 80% R1/ | 0.10 | 0.26 | 0.04 |
| 20% R2 | | | |

TABLE 3
Dielectric Breakdown

| | | Dielectric | Dielectric |
|---|---|---|---|
| | Thickness | Strength | Strength Std Dev |
| Material | mm | kV/mm | kV/mm |
| R1 | 0.14 | 62 | 16 |
| 45% F1 in R1 | 0.13 | 66 | 3 |
| 45% F1 in 80% R1/ | 0.17 | 66 | 9 |
| 20% R2 | | | |

Thus, embodiments of THERMALLY CONDUCTIVE DIELECTRIC FILM are disclosed.

All references and publications cited herein are expressly incorporated herein by reference in their entirety into this disclosure, except to the extent they may directly contradict this disclosure. Although specific embodiments have been illustrated and described herein, it will be appreciated by those of ordinary skill in the art that a variety of alternate and/or equivalent implementations can be substituted for the specific embodiments shown and described without departing from the scope of the present disclosure. This application is intended to cover any adaptations or variations of the specific embodiments discussed herein. Therefore, it is intended that this disclosure be limited only by the claims and the equivalents thereof. The disclosed embodiments are presented for purposes of illustration and not limitation.

1. A thermally conductive dielectric film comprising:
a thermoplastic layer comprising polyester segments and 5 to 30% by wt polyether amide segments;
the thermally conductive dielectric film having a thickness of less than 100 micrometers.

2. The film according to claim 1 wherein the thermoplastic layer is substantially free of inorganic filler material.

3. The film according to claim 1, wherein the thermally conductive dielectric film has a Graves area per mil value of at least 100 (lbs*% displacement)/mil, or at least 200 (lbs*% displacement)/mil, or at least 300 (lbs*% displacement)/mil, or at least 350 (lbs*% displacement)/mil.

4. The film according to claim 1, wherein the thermally conductive dielectric film has a thickness in a range from 25 to 100 micrometers, or from 25 to 75 micrometers, or from 25 to 50 micrometers, or from 25 to 40 micrometers.

5. The film according to claim 1, wherein the thermally conductive dielectric film has a thermal conductivity value of 0.20 W/(m-K) or greater, or 0.25 W/(m-K) or greater, or 0.3 W/(m-K) or greater.

6. The film according to claim 1, wherein the thermally conductive dielectric film has breakdown strength of at least 50 kV/mm, or at least 60 kV/mm, or at least 65 kV/mm.

7. The film according to claim 1, wherein the polyester segments comprise polyethylene terephthalate or polyethylene naphthalate segments.

8. The film according to claim 1, wherein the thermoplastic layer is uniaxially orientated or biaxially orientated.

9. The film according to claim 1, wherein the thermoplastic layer comprises polyethylene terephthalate segments and 5 to 20% by wt polyether amide segments.

10. A thermally conductive dielectric film comprising:
a thermoplastic layer comprising polyester segments and 5 to 30% by wt polyether amide segments;
a thermally conductive filler dispersed in the thermoplastic layer; and
the thermally conductive dielectric film having a thickness of 100 micrometers or less.

11. The film according to claim 10, wherein the thermally conductive dielectric film has a Graves area per mil value of at least 10 (lbs*% displacement)/mil, or at least 20 (lbs*% displacement)/mil, or at least 30 (lbs*% displacement)/mil, or at least 50 (lbs*% displacement)/mil.

12. The film according to claim 10, wherein the thermally conductive dielectric film has a thickness in a range from 25 to 100 micrometers, or from 25 to 75 micrometers, or from 25 to 50 micrometers, or from 25 to 40 micrometers.

13. The film according to claim 10, wherein the thermally conductive dielectric film has a thermal conductivity value of 0.20 W/(m-K) or greater, or 0.25 W/(m-K) or greater, or 0.3 W/(m-K) or greater.

14. The film according to claim 10, wherein the thermally conductive dielectric film has breakdown strength of at least 50 kV/mm, or at least 60 kV/mm, or at least 65 kV/mm.

15. The film according to claim 10, wherein the polyester segments comprise polyethylene terephthalate or polyethylene naphthalate segments.

16. The film according to claim 10, wherein the thermoplastic layer is uniaxially orientated or biaxially orientated.

17. The film according to claim 10, wherein the thermoplastic layer comprises polyethylene terephthalate segments and 5 to 20% by wt polyether amide segments.

18. The film according to claim 10, wherein the filler comprises inorganic particles having a D₉₉ value of 25 micrometers or less, or 20 micrometers or less, or 15 micrometers or less, and a median size value in a range from 1 to 10 micrometers, or from 1 to 5 micrometers, or from 1 to 3 micrometers.

19. The film according to claim 10, wherein the filler comprises homogenous substantially spherical inorganic particles.

20. The film according to claim 10, wherein the filler comprises alumina.
